(19) United States
(12) Patent Application Publication
(10) Pub. No.: US 2017/0040146 A1
(43) Pub. Date: Feb. 9, 2017

(54) PLASMA ETCHING DEVICE WITH PLASMA ETCH RESISTANT COATING

(71) Applicant: Lam Research Corporation, Fremont, CA (US)

(72) Inventors: Lihua Li HUANG, Pleasanton, CA (US); Hong SHIH, Santa Clara, CA (US); Lin XU, Katy, TX (US); John DAUGHERTY, Fremont, CA (US)

(21) Appl. No.: 14/817,115

(22) Filed: Aug. 3, 2015

(51) Int. Cl. H01J 37/32; C23C 14/30; C23C 16/30; C23C 14/06

(52) U.S. Cl. CPC H01J 37/32495; H01J 37/32119; H01J 37/3244; H01J 37/32715; C23C 14/06; C23C 14/30; C23C 16/30; H01J 2237/334

(57) ABSTRACT

An apparatus for use in a plasma processing chamber is provided. The apparatus comprises part body and a coating with a thickness of no more than 30 microns consisting essentially of a Lanthanide series or Group III or Group IV element in an oxyfluoride covering a surface of the part body.

### BACKGROUND

The present disclosure relates to the manufacturing of semiconductor devices. More specifically, the disclosure relates to coating chamber surfaces used in manufacturing semiconductor devices.

During semiconductor wafer processing, plasma processing chambers are used to process semiconductor devices. Coatings are used to protect chamber surfaces.

### SUMMARY

To achieve the foregoing and in accordance with the purpose of the present disclosure, an apparatus for use in a plasma processing chamber is provided. The apparatus comprises part body and a coating with a thickness of no more than 30 microns consisting essentially of a Lanthanide series or Group III or Group IV element in an oxyfluoride covering a surface of the part body.

In another manifestation, a method of forming an edge ring for use in a plasma processing chamber is provided. A green edge ring is formed consisting essentially of a Lanthanide series or Group III or Group IV element in an oxyfluoride. The green edge ring is sintered.

In another manifestation, an apparatus for processing a substrate is provided. A processing chamber is provided. A substrate support for supporting the substrate is within the processing chamber. A gas inlet for providing gas into the processing chamber above a surface of the substrate. A window for passing RF power into the chamber, where the window comprises a window body and a coating consisting essentially of a Lanthanide series or Group III or Group IV element in an oxyfluoride covering a surface of the window body, wherein the coating is no more than 30 microns thick.

These and other features of the present invention will be described in more detail below in the detailed description of the invention and in conjunction with the following figures.

### BRIEF DESCRIPTION OF THE DRAWINGS

The present disclosure is illustrated by way of example, and not by way of limitation, in the figures of the accompanying drawings and in which like reference numerals refer to similar elements and in which:

FIG. 1 is a schematic view of an etch reactor that may be used in an embodiment.

FIG. 2 is an enlarged cross-sectional view of a power window.

FIG. 3 is an enlarged cross-sectional view of the gas injector.

FIG. 4 is an enlarged cross-sectional view of part of an edge ring.

### DETAILED DESCRIPTION OF THE PREFERRED EMBODIMENTS

The present invention will now be described in detail with reference to a few preferred embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to not unnecessarily obscure the present invention.

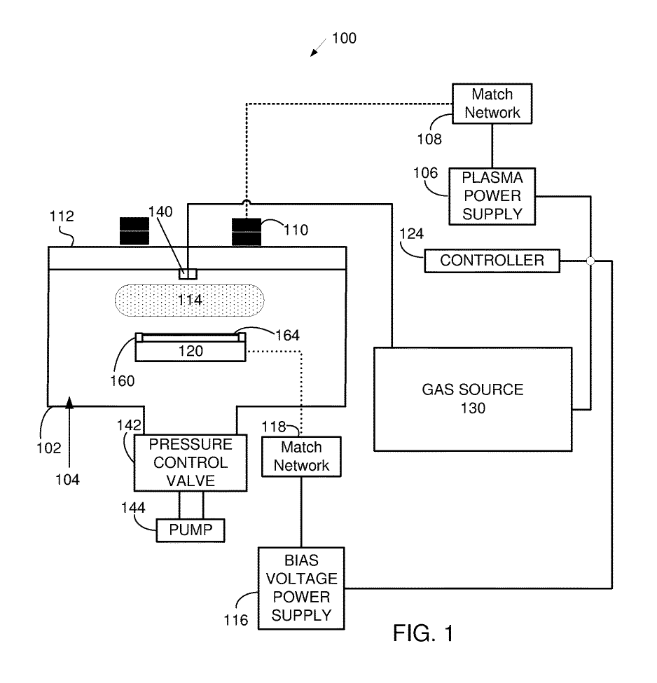

To facilitate understanding, FIG. 1 schematically illustrates an example of a plasma processing chamber 100 which may be used in an embodiment. The plasma processing chamber 100 includes a plasma reactor 102 having a plasma processing confinement chamber 104 therein. A plasma power supply 106, tuned by a match network 108, supplies power to a TCP coil 110 located near a power window 112 to create a plasma 114 in the plasma processing confinement chamber 104 by providing an inductively coupled power. The TCP coil (upper power source) 110 may be configured to produce a uniform diffusion profile within the plasma processing confinement chamber 104. For example, the TCP coil 110 may be configured to generate a toroidal power distribution in the plasma 114. The power window 112 is provided to separate the TCP coil 110 from the plasma processing confinement chamber 104 while allowing energy to pass from the TCP coil 110 to the plasma processing confinement chamber 104. A wafer bias voltage power supply 116 tuned by a match network 118 provides power to an electrode 120 to set the bias voltage on the substrate 164 which is supported by the electrode 120. A controller 124 sets points for the plasma power supply 106, gas source/gas supply mechanism 130, and the wafer bias voltage power supply 116.

The plasma power supply 106 and the wafer bias voltage power supply 116 may be configured to operate at specific radio frequencies such as, for example, 13.56 MHz, 27 MHz, 2 MHz, 60 MHz, 400 kHz, 2.54 GHz, or combinations thereof. Plasma power supply 106 and wafer bias voltage power supply 116 may be appropriately sized to supply a range of powers in order to achieve desired process performance. For example, in one embodiment of the present invention, the plasma power supply 106 may supply the power in a range of 50 to 5000 Watts, and the wafer bias voltage power supply 116 may supply a bias voltage of in a range of 20 to 2000 V. In addition, the TCP coil 110 and/or the electrode 120 may be comprised of two or more sub-coils or sub-electrodes, which may be powered by a single power supply or powered by multiple power supplies.

As shown in FIG. 1, the plasma processing chamber 100 further includes a gas source/gas supply mechanism 130. The gas source 130 is in fluid connection with plasma processing confinement chamber 104 through a gas inlet, such as a gas injector 140. The gas injector 140 may be located in any advantageous location in the plasma processing confinement chamber 104, and may take any form for injecting gas. Preferably, however, the gas inlet may be configured to produce a “tunable” gas injection profile, which allows independent adjustment of the respective flow of the gases to multiple zones in the plasma process confinement chamber 104. The process gases and byproducts are removed from the plasma process confinement chamber 104 via a pressure control valve 142 and a pump 144, which also serve to maintain a particular pressure within the plasma processing confinement chamber 104. The pressure control valve 142 can maintain a pressure of less than 1 Torr during processing. An edge ring 160 is placed around the wafer 164. The gas source/gas supply mechanism 130 is controlled by the controller 124. A Kiyo by Lam Research Corp. of Fremont, Calif., may be used to practice an embodiment.

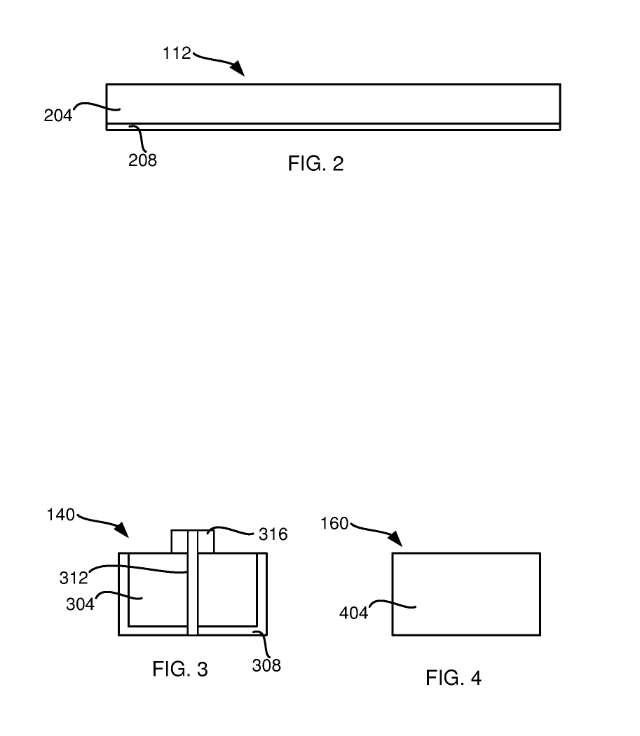

FIG. 2 is an enlarged cross-sectional view of the power window 112. The power window 112 comprises a window body 204 and a coating 208 covering at least one surface of the window body 204. In this example, the coating 208 is only on one surface of the window body 204. The window body 204 may be of one or more different materials. Preferably, the window body 204 is ceramic. More preferably, the window body 204 comprises at least one of silicon (Si), quartz, silicon carbide (SiC), silicon nitride (SiN), aluminum oxide (AlO), aluminum nitride (AlC), or aluminum carbide (AlC). The coating 208 consists essentially of a Lanthanide series or Group III or Group IV element in an oxyfluoride. More preferably, the coating consists essentially of yttrium, lanthanum, zirconium, samarium (Sm), gadolinium (Gd), dysprosium (Dy), erbium (Er), ytterbium (Yb), or thulium (Tm) in an oxyfluoride. More preferably, the coating 208 consists essentially of yttrium oxyfluoride. Preferably, the coating 208 is no more than 30 μm thick. More preferably, the coating 208 is 5-20 μm thick. Most preferably, the coating 208 is 10-18 μm thick. Preferably, the coating 208 is 99.7% pure. Preferably, the coating 208 is high density with a porosity of less than 1%. More preferably, the coating 208 has a porosity of less than 0.5%. To provide such a uniform, high density, low porosity, and thin coating, preferably the coating 208 is formed by physical vapor deposition. More preferably, the physical vapor deposition is electron beam physical vapor deposition. Most preferably, the physical vapor deposition is ion assisted electron beam deposition. Preferably, the coating has a density of at least 5 g/cm³.

FIG. 3 is an enlarged cross-sectional view of the gas injector 140. The gas injector 140 comprises an injector body 304 and a coating 308 covering at least one surface of the injector body 304. In this example, the coating 308 is on at least two surfaces of the injector body 304. The injector body 304 has a bore hole 312, through which the gas flows. In some embodiments, the coating 308 may line the bore hole 312. The gas injector 140 may also have a mount 316 for fixing the gas injector 140 to the power window 112. The injector body 304 may be of one or more different materials. Preferably, the injector body 304 is ceramic. More preferably, the injector body 304 comprises at least one of silicon (Si), quartz, silicon carbide (SiC), silicon nitride (SiN), aluminum oxide (AlO), aluminum nitride (AlC), or aluminum carbide (AlC). The coating 308 consists essentially of a Lanthanide series or Group III or Group IV element in an oxyfluoride. More preferably, the coating 308 consists essentially of yttrium oxyfluoride. Preferably, the coating 308 is no more than 30 μm thick. More preferably, the coating 308 is 2-20 μm thick. Most preferably, the coating 308 is 10-18 μm thick. Preferably, the coating 308 is 99.7% pure. Preferably, the coating 308 is high density with a porosity of less than 1%. To provide such a uniform, high density, low porosity, and thin coating, preferably the coating 308 is formed by physical vapor deposition or chemical vapor deposition. More preferably, the physical vapor deposition is electron beam physical vapor deposition. Most preferably, the physical vapor deposition is ion assisted electron beam deposition.

FIG. 4 is an enlarged cross-sectional view of part of the edge ring 160. The edge ring 160 comprises a ring body 404. A method of making the edge ring 160 would form a ceramic consisting essentially of a Lanthanide series or Group III or Group IV element in an oxyfluoride into a green edge ring. The green edge ring is sintered to fuse ceramic particles together. Preferably, the ceramic consists essentially of yttrium oxyfluoride. The density of the ring body is at least 5 g/cm³.

In some embodiments, the gas source provides a halogen containing gas, which is formed into a halogen containing plasma. It has been unexpectedly found that coatings comprising at least one of a Group III or Group IV element in an oxyfluoride are highly etch resistant. It has been found that providing a porosity of less than 1% increases etch resistance.

In other embodiments, other components such as the chamber walls or the electrostatic chuck may also have an etch resistant coating or body. In other embodiments, the plasma processing chamber may be a capacitively coupled plasma processing chamber. In such chambers components such as confinement rings and upper electrodes may have the etch resistant coatings.

If parts of the chamber only have an yttrium oxide coating, a fluorine containing plasma would convert some of the yttrium oxide coating into yttrium oxyfluoride particles. The yttrium oxyfluoride particles would flake off, becoming contaminants. It has been unexpectedly found that a high density and low porosity yttrium oxyfluoride coating would not produce such particles and would be more etch resistant to fluorine containing plasmas. In addition, it has been unexpectedly found that a coating of yttrium oxyfluoride may be deposited with a thickness of 15-16 μm without cracking caused by stress, allowing for a coating that would be much thicker than an yttrium oxide coating, and would allow the production of a coating that would have more than twice the life expectancy of an yttrium oxide coating.

While this disclosure has been described in terms of several preferred embodiments, there are alterations, permutations, modifications, and various substitute equivalents, which fall within the scope of this disclosure. It should also be noted that there are many alternative ways of implementing the methods and apparatuses of the present disclosure. It is therefore intended that the following appended claims be interpreted as including all such alterations, permutations, and various substitute equivalents as fall within the true spirit and scope of the present disclosure.

1. An apparatus for use in a plasma processing chamber, comprising:
a part body; and
a coating with a thickness of no more than 30 microns consisting essentially of a Lanthanide series or Group III or Group IV element in an oxyfluoride covering at least part of a surface of the part body, wherein the coating is deposited by physical vapor deposition or chemical vapor deposition.

2. The apparatus, as recited in claim 1, wherein the coating has a porosity of less than 1%.

3. The apparatus, as recited in claim 2, wherein the part body is of ceramic.

4. The apparatus, as recited in claim 3, wherein the part body forms an RF window or a gas injector.

5. The apparatus, as recited in claim 4, wherein the coating is deposited by electron beam physical vapor deposition.

6. The apparatus, as recited in claim 4, wherein the coating is deposited by ion assisted electron beam deposition.

7. (canceled)

8. The apparatus, as recited in claim 1, wherein the coating consists essentially of yttrium oxyfluoride.

9. The apparatus, as recited in claim 8, wherein the coating has a thickness of 2-18 μm.

10. The apparatus, as recited in claim 1, wherein the coating consists essentially of yttrium, lanthanum, zirconium, samarium (Sm), gadolinium (Gd), dysprosium (Dy), erbium (Er), ytterbium (Yb), or thulium (Tm) in an oxyfluoride.

11. (canceled)

12. The apparatus, as recited in claim 2, wherein the coating consists essentially of yttrium oxyfluoride.

13. The apparatus, as recited in claim 2, wherein the coating consists essentially of yttrium, lanthanum, zirconium, samarium (Sm), gadolinium (Gd), dysprosium (Dy), erbium (Er), ytterbium (Yb), or thulium (Tm) in an oxyfluoride.

14. The apparatus, as recited in claim 2, wherein the coating has a thickness of 15-16 μm.

15. A method of forming an edge ring for use in a plasma processing chamber, comprising:
forming a green edge ring consisting essentially of a Lanthanide series or Group III or Group IV element in an oxyfluoride; and sintering the green edge ring.

16. The method, as recited in claim 15, wherein the green edge ring consisting essentially of yttrium oxyfluoride.

17. An apparatus for processing a substrate, comprising:
a processing chamber;
a substrate support for supporting the substrate within the processing chamber;
a gas inlet for providing gas into the processing chamber above a surface of the substrate;
a window for passing RF power into the chamber, comprising:
a window body; and
a coating consisting essentially of a Lanthanide series or Group III or Group IV element in an oxyfluoride covering at least part of a surface of the window body, wherein the coating is no more than 30 microns thick, wherein the coating is deposited by physical vapor deposition or chemical vapor deposition.

18. The apparatus, as recited in claim 17, wherein the coating consists essentially of yttrium oxyfluoride.
